(19) United States
(12) Patent Application Publication
(10) Pub. No.: US 2011/0012110 A1
(43) Pub. Date: Jan. 20, 2011

(54) SEMICONDUCTOR FIELD EFFECT TRANSISTOR AND METHOD FOR FABRICATING THE SAME

(75) Inventors: Hiroyuki Sazawa, Tsukuba-shi (JP); Mitsuaki Shimizu, Tsukuba-shi (JP); Shuichi Yagi, Tsukuba-shi (JP); Hajime Okumura, Tsukuba-shi (JP)

Correspondence Address: FITCH, EVEN, TABIN & FLANNERY, P. O. BOX 18415, WASHINGTON, DC, 20036, US

(73) Assignee: SUMITOMO CHEMICAL COMPANY, LIMITED, Tokyo (JP)

(21) Appl. No.: 12/293,330

(22) PCT Filed: Mar. 16, 2007
(86) PCT No.: PCT/JP2007/055337

§ 371 Date: Oct. 4, 2010

(30) Foreign Application Priority Data
Mar. 17, 2006 (JP) 2006-073610

(51) Int. Cl. H01L 29/04; H01L 21/336

(52) U.S. Cl. 257/51; 438/591; 257/E21.19; 257/E29.003

(57) ABSTRACT

A gallium nitride based field effect transistor having good current hysteresis characteristics in which forward gate leakage can be reduced. In a gallium nitride-based field effect transistor (100) having a gate insulation film (108), part or all of a material constituting the gate insulation film (108) is a dielectric material having a relative dielectric constant of 9-22, and a semiconductor crystal layer A (104) in contact with the gate insulation film (108) and a semiconductor crystal layer B (103) in the vicinity of the semiconductor crystal layer A (104) and having a larger electron affinity than the semiconductor crystal layer A (104) constitute a hetero junction. A hafnium oxide such as HfO₂, HfAlO, HfAlON or HfSiO is preferably contained, at least partially, in the material constituting the gate insulation film (108).

### TECHNICAL FIELD

The present invention relates to a semiconductor field effect transistor, a semiconductor integrated circuit and a method for fabricating the same.

### BACKGROUND ART

Semiconductor field effect transistors are widely used as electronic components such as amplifiers or switches, and are classified into several categories depending on the forms of current pathway (channel). An example includes a field effect transistor utilizing a two-dimensional electron gas (2DEG). Such field effect transistors are divided into two types depending on the forms of the interfaces at which a 2DEG is formed. In the first type a 2DEG is formed at an oxide film/semiconductor crystal interface. In the second type a 2DEG is formed at a similar semiconductor crystal/semiconductor crystal interface. A representative example of the first type is a Si-MOS field effect transistor, and a representative example of the second type is a GaN high electron mobility field effect transistor (GaN-HEMT).

A Si-MOS field effect transistor comprises a polarity reversal channel which is formed at a Si oxide film/Si semiconductor crystal interface by controlling a gate bias. The Si-MOS field effect transistor has a great advantage of being able to induce more carriers at the interface within the range of pressure resistance of the oxide film when a gate bias is applied to the forward direction (positive voltage in the case of N-type channel), thereby obtaining a higher current density. However, there are problems that since electrons run on an interface of different crystal system, the electron transit speed becomes insufficient by scattering due to crystal lattice disorder at the interface, and therefore there is a limit on amplification of high frequency signal or fast switching.

Meanwhile, in the case of a GaN-HEMT, it is configured to form a channel that induces carriers at a bonded interface by bonding an AlGaN layer and a GaN layer, similar semiconductor crystals having different electron affinities. Since the interface is a hetero-bonded interface of similar crystals, scattering of electrons is small, high electron transit speed can be achieved, and therefore it is suitable for amplification of high frequency signal or fast switching. However, in the case of the GaN-HEMT, it is almost impossible to improve the drain current density by applying a forward gate bias. This is because so-called “gate leakage” phenomenon occurs. This phenomenon is caused by allowing induced carriers to be easily leaked in a gate electrode through crystals having a small electron affinity due to the small difference in electron affinity among similar crystals. In order to improve this problem, there is a known method of increasing the Al content of the AlGaN layer to expand the difference in electron affinity between an AlGaN layer and a GaN layer (Non-Patent Document 1). Another known method is to reduce forward gate leakage by a laminating film made of a material having a smaller electron affinity than a semiconductor crystal layer, in contact with the semiconductor crystal layer (Non-Patent Document 2).
Non-Patent Document 1: Masataka higashiwaki et al., Japanese Journal of Applied Physics, Vol. 44. No. 16, 2005
Non-Patent Document 2: Narihiko maeda et al., Applied Physics Letter 87, 073504, 2005

### DISCLOSURE OF THE INVENTION

### Problem to be Solved by the Invention

However, according to the method of increasing the Al content of AlGaN layer, there has been caused problems such as an increase in alloy scattering at the interface and a deterioration of crystallinity due to expansion of interfacial lattice mismatch. As a result, the prospective effects have not been provided yet.

Further, the method of laminating a film made of a material having a smaller electron affinity than a semiconductor crystal layer in contact with the semiconductor crystal layer can reduce a backward leakage current considerably, but it is not effective for reducing a forward leakage current so that a sufficient gate vias cannot be applied. Therefore, there is a limit to practical use.

Thus, in accordance with the conventional techniques, it is difficult to produce a semiconductor field effect transistor having all of high electron transit speed, high gain and high drain current density.

It is an object of the present invention to provide a high performance gallium nitride field effect transistor capable of solving the above described problems in the conventional techniques.

It is another object of the present invention to provide a gallium nitride field effect transistor having good current hysteresis characteristics in which the forward gate leakage can be reduced.

It is another object of the present invention to provide a gallium nitride field effect transistor capable of achieving high electron speed, high gain and high gain current density.

### Means for Solving the Problem

In order to solve the above problems, a field effect transistor according to the present invention has carriers as a channel, wherein the carriers are induced at a hetero interface between gallium nitride semiconductor crystal layers A and B, and further the field effect transistor has a gate insulation film is provided between the semiconductor crystal layer A and a gate electrode so as to contain a hafnium oxide, at least partially, in the material constituting the gate insulation film.

The invention of a semiconductor field effect transistor as proposed in claim 1 relates to a gallium nitride semiconductor field effect transistor having a gate insulation film and a hetero junction composed of a semiconductor crystal layer A and a semiconductor crystal layer B, wherein a part or all of a material constituting the gate insulation film is a dielectric material having a relative dielectric constant of 9 to 22, and wherein the semiconductor crystal layer A is in contact with the gate insulation film and the semiconductor crystal layer B in the vicinity of the semiconductor crystal layer A has a larger electron affinity than the semiconductor crystal layer A.

The invention as proposed in claim 2 relates to the semiconductor field effect transistor according to claim 1 wherein the semiconductor crystal layer A is an AlₓIn_{y}Ga_{(1-x-y)}N crystal (0≦x, y≦1, x+y≦1).

The invention as proposed in claim 3 relates to the semiconductor field effect transistor according to claim 1 or 2 wherein a part or all of the material constituting the gate insulation film contains a hafnium oxide is proposed.

The invention as proposed in claim 4 relates to the semiconductor field effect transistor according to any one of claims 1 to 3 wherein a part or all of the material constituting the gate insulation film contains HfₓAl₁₋ₓO_{y}(0<x<1, 1≦y≦2) is proposed.

The invention as proposed in claim 5 relates to the semiconductor integrated circuit having the field effect transistor according to any one of claims 1 to 4.

The invention as proposed in claim 6 relates to the method for fabricating the semiconductor field effect transistor according to any one of claims 1 to 4, which further contains the steps of: forming an insulation layer and then performing heat treatment at the temperature of 300° C. or higher.

The invention as proposed in claim 7 relates to the method for fabricating a semiconductor integrated circuit field effect transistor according to claim 6, which further contains the steps of: forming a gate electrode and then performing heat treatment at the temperature of 300° C. or higher.

The invention as proposed in claim 8 relates to the method for fabricating the semiconductor integrated circuit according to claim 5, which further contains the steps of: forming an insulation layer and then performing heat treatment at the temperature of 300° C. or higher.

The invention as proposed in claim 9 relates to the method for fabricating the semiconductor integrated circuit according to claim 8, which further contains the steps of: forming a gate electrode and then performing heat treatment at the temperature of 300° C. or higher.

### Effect of the Invention

According to the present invention, since a channel layer is formed at a similar semiconductor crystal layer interface with small electron scattering, high mobility can be provided. Furthermore, since optimal dielectric constant is disposed on the surface of the crystal layer, a large forward gate bias can be also applied. As a result, a high performance field effect transistor that achieves extremely large drain current density can be provided, which has an extreme significance in industrial uses.

### BEST MODE FOR CARRYING OUT THE INVENTION

An exemplary embodiment of the present invention will now be described in detail with reference to a drawing.

FIG. 1 is a sectional view of an exemplary embodiment of a field effect transistor according to the present invention. In this embodiment, a semiconductor integrated circuit having a plurality of GaN-HEMTs of gallium nitride field effect transistors according to the present invention which are formed on a base substrate 101 are taken as an example, but the present invention is not limited to the GaN-HEMTs or the semiconductor integrated circuit.

A semiconductor integrated circuit 1 shown in

FIG. 1 has a plurality of field effect transistors 100 according to the present invention, wherein the plurality of field effect transistors 100 are formed on a base substrate 101. However, only one of the plurality of field effect transistors 100 is shown in FIG. 1 for simplification. It is needless to say that various devices other than the field effect transistors 100 may be provided on the semiconductor integrated circuit 1, and the semiconductor integrated circuit 1 may also consist only of the field effect transistors 100 which are provided thereon. The field effect transistors 100 are herein constituted as a GaN-HEMT of a gallium nitride field effect transistor.

Attention will now be focused on one of the field effect transistors 100 with reference to FIG. 1 to explain the configuration and operation thereof. The same applies to other field effect transistors that are not shown. The field effect transistor 100 (i.e. one of the field effect transistors 100) is formed on a substrate comprising a buffer layer 102, which is formed on a base substrate 101.

As a base substrate 101, any single crystal substrates such as SiC, sapphire, Si and GaN in which lattice constant difference between an epitaxial layer formed on the base substrate 101 and the base substrate 101 is small or little can be used. Although the base substrate 101 is preferably semi-insulative, a conductive substrate can also be used. Substrates having various sizes are commercially available, but they are not limited in size. Further, substrates having various off-angles and off-directions are commercially available, and they can be used without limitation. As a plane direction of the base substrate 101, both polar and nonpolar planes can be used without limitation. Accordingly, commercially available substrates can be used as the base substrate 101.

A buffer layer 102 provided on the base substrate 101 is introduced in order to reduce a distortion caused by lattice constant difference between the base substrate 101 and various semiconductor crystal layers provided on the base substrate 101 and in order to avoid the influence of impurities contained in the base substrate 101. As a material for the buffer layer 102, AlN, AlGaN, GaN or the like can be used. The buffer layer 102 can be formed by laminating such materials on the base substrate 101 according to the processes such as MOPVE, MBE and HVPE. Source materials suitable for each growth process are commercially available, so they can be used. The thickness of the buffer layer 102 is not limited in particular, but is typically in the range of 3,000 Å to 20 μm.

A semiconductor crystal layer B103 is formed on the buffer layer 102, and another semiconductor crystal layer A104 is formed on the semiconductor crystal layer B103. As shown in FIG. 1, one surface of the semiconductor crystal layer B103 directly contacts with one surface of the semiconductor crystal layer A104, which allows a channel to be formed at an interface between the semiconductor crystal layers B103 and A104 at the time of gate bias application and at the side of the semiconductor crystal layer B103.

In order to form the above described channel, the semiconductor crystal layer B103 needs to have a larger electron affinity than the semiconductor crystal layer A104. Two semiconductor crystal layers B103 and A104, which are provided to form the channel, will now be described in detail.

As a material for the semiconductor crystal layer B103, GaN can be used. The lamination of the semiconductor crystal layer B103 can be conducted in the same processes as the case of the buffer layer 102, for example MOVPE, MBE and HVPE. As in the case of the buffer layer 102, source materials suitable for each growth process are commercially available, so they can be used. The thickness of the semiconductor crystal layer B103 is not limited in particular, but it ranges from 3,000 Å to 5 μm, more preferably from 5,000 Å to 3 μm, and still more preferably from 700 Å to 2 μm.

The semiconductor crystal layer A104 can be formed by crystal growth of AlGaN or AlInGaN on the semiconductor crystal layer B103. The crystal growth process on the semiconductor crystal layer B103 is conducted in the same manner as in the case of the semiconductor crystal layer B103. Regarding the semiconductor crystal layer A104, the crystal growth of AlGaN causes a lattice constant difference between the semiconductor crystal layers B103 and A104, thereby generating a piezoelectric field and inducing free carriers at the interface and at the side of the semiconductor crystal layer B103 (GaN layer side).

Meanwhile, when crystal growth of AlInGaN is conducted as the semiconductor crystal layer A104, the generation of a piezoelectric field is avoided by adjusting a composition ratio between Al and In in addition to lattice matching of the semiconductor crystal layers B103 and A104, and therefore the mode that free carriers are not generated at a gate bias zero and no channel is formed, i.e., E-mode operating field effect transistor can be produced.

There are no particular limitations on the materials of the semiconductor crystal layer A104 for the field effect transistor according to the present invention. However, in any case, in order that a channel can be formed at the side of the semiconductor crystal layer B103 of an interface between the semiconductor crystal layers B103 and A104 at the application of a gate bias as well as the semiconductor crystal layer B103 can provide a larger electron affinity than the semiconductor crystal layer A104, it is important to select material systems and compositions.

In the semiconductor crystal layer A104, it is preferable to increase the Al content so that the semiconductor crystal layer A104 has a sufficiently smaller electron affinity than the semiconductor crystal layer B103. However, as described above, the larger Al content causes deterioration of the crystallinity of an AlGaN layer, resulting in performance degradation or operation failure of the resulting field effect transistor. Thus, it is necessary to determine the optimal value by taking the above factors into account. In view of such circumstances, in general, the Al content ranges preferably from 0.1 to 0.6, more preferably from 0.15 to 0.5, and still more preferably from 0.2 to 0.4.

The lamination of the semiconductor crystal layer A104 can be conducted in the same processes as the cases of the buffer layer 102 and the semiconductor crystal layer B103, i.e. MOVPE, MBE, HVPE and the like. The source materials suitable for each growth process are commercially available, so they can be used. The thickness of the semiconductor crystal layer A104 is not limited in particular, but it ranges from 30 Å to 600 Å, more preferably from 100 Å to 500 Å, still more preferably from 150 Å to 400 Å.

In this embodiment, the semiconductor crystal layer A104 was prepared as a single layer. However, the semiconductor crystal layer A104 may take repeated laminate structures of a GaN layer and an AlGaN layer or repeated laminate structures of an InGaN layer and an AlGaN layer, which have the thickness within the limitation of elastic deformation.

On the semiconductor crystal layer A104, in addition to the formations of a source electrode 105 and a drain electrode 106, a gate electrode 109 is formed through a gate insulation film 108. A separating layer for separating devices is expressed at a reference numeral 107. By providing the separating layer 107, a plurality of the field effect transistors 100 having the above layer structures are formed on a substrate so as not to mutually and electrically cause the interference.

A leak current at the time of applying a forward bias voltage to a gate electrode 109 can be reduced by providing a gate insulation film 108, thereby applying a large forward voltage. In this case, as the gate insulation film 108 becomes thicker, the leak current can be lessened. However, when the gate insulation film 108 increases in thickness, an intermediate level of electron is easily formed at the interface between the gate insulation film 108 and the semiconductor crystal layer A104, and therefore causes current hysteresis.

Thus, the present inventors have conducted an intensive investigation on a material for a gate insulation film of a gallium nitride field effect transistor. As a result, it has been found that by using a hafnium oxide-containing material as a material for the gate insulation film, a high performance gallium nitride field effect transistor which can suppress the generation of current hysteresis and reduce the leak current at the time of applying the forward bias voltage is achieved.

A dielectric material having a relative dielectric constant of 9 or more to 22 or less is formed on the semiconductor crystal layer A104 as the gate insulation film 108. In the case of departing from the above range, it is impossible to effectively suppress the forward leak current. Although the dielectric material having a relative dielectric constant of 9 or more to 22 or less is effective for reducing the gate leakage, the relative dielectric constant of 13 to 18 is more preferable. Examples of the material with a relative dielectric constant of 9 or more to 22 or less include Cr₂O₃, CuO, FeO, PbCO₃, PbCl₂, PbSO₄, SnO₂, ZrO₂, ZrSiO₄, Ta₂O₅, TiO₂, BaTiO, HfSiO₂, HfAlO, La₂O₃, CaHfO and HfAlON. All these material systems are effective, but in view of less current hysteresis during driving, La₂O₃, CuO, HfSiO₂, HfO₂, HfAlO and CaHfO are more preferable. HfO₂, HfAlON, HfAlO and HfSiO are still more preferable. HfAlO is most preferable.

For the reasons of less leak and so on, crystal systems of these materials are preferably amorphous or single crystal in the case of using as a gate insulation film 108. In view of ease of producing a film and so on, amorphous is more preferable.

Thus, when a part or all of a material constituting the gate insulation film 108 contains a hafnium oxide, for example, HfₓAl₁₋ₓO_{y}(0<x<1, 1≦y≦2), a leak current can be reduced effectively. Accordingly, the control of the leak current becomes possible.

The gate insulation film 108 may take laminate structures of the above materials and other materials. For example, it is possible to employ laminate structures in which SiN known as an insulation film capable of suppressing a current collapse phenomenon is adapted to be inserted in the intervening space with the above materials illustrated as being able to be used for the gate insulation film 108 at the thickness of from 1 nm to 10 nm. In this case, there are no particular limitations on the types of insulation film materials to be combined. Considering effective leak current suppression, mutual conductance, hysteresis, and the like, the thickness thereof ranges preferably from 3 nm to 40 nm, more preferably from 5 nm to 30 nm, and most preferably from 7 nm to 20 nm.

Furthermore, it is also possible to employ a structure in which a part of the semiconductor crystal layers B103 and/or A104 is removed by etching (recess structure). This enables the improvement of a field effect transistor gain or the performance of E-mode operation by adjusting threshold voltage to be positive.

The gate insulation film 108 can be formed by utilizing the processes such as a thermal CVD, a plasma CVD, an ALCVD, a MOCVD, a MBE, an evaporation and a spattering.

Current hysteresis can be reduced by forming the gate insulation film 108 according to the above processes, and then by carrying out annealing treatment. Therefore, in the case of producing a semiconductor integrated circuit 1 shown in FIG. 1 or producing a stand-alone field effect transistor 100 having a configuration shown in FIG. 1, annealing treatment after forming the gate insulation film 108 is effective to improve the current hysteresis characteristics thereof.

This annealing treatment may be conducted at the appropriate timing of the period from after the formation of the gate insulation film 108 to device sealing. The annealing treatment is generally conducted at temperatures of 300° C. or higher and also within the range of heat resistance of the gate insulation film 108 (in the range capable of maintaining amorphous). Typically, it is in the range of 300° C. to 900° C. In the case of performing annealing treatment at temperatures in the range of 300° C. to 900° C., the current hysteresis characteristics thereof can be further improved, compared to the case without annealing treatment. There are no particular limitations on the time of annealing treatment, but it is preferably in the range of 10 sec to 60 min in view of the balance of effectiveness and industrial efficiency. Atmosphere is preferably nitrogen and/or Ar, and more preferably nitrogen.

As materials for a gate electrode 109 which is formed on the gate insulation film 108, a source electrode 105 and a drain electrode 106, the materials and methods used in typical GaN-HEMT devices can be used as they are. Therefore, a material for the gate electrode 108 include Ni/Au, Pt and the like. Examples of materials for the source electrode 105 and the drain electrode 106 include Ti/Al, Ti/Mo and the like. These can be formed by a spattering, an evaporation, a CVD or the like.

Annealing treatment may be performed after formation of a gate electrode. In this case, it is performed at the temperature range which can reduce hysteresis and gives no damage to gate electrode materials. Such temperature range is determined in view of heat resistance of gate electrode materials, but is generally in the range of 300° C. to 600° C.

Although the present invention has been described hereinabove based on an exemplary embodiment, such embodiment of the present invention is merely illustrations, and the technical scope of the present invention is not limited thereto. The technical scope of the present invention is defined by the claims, and is further intended to cover meanings equivalent to the claims and any modifications within the scope of the claims.

### Examples

The present invention will now be described in detail with reference to the following Examples, but they are merely examples, and the present invention should not be limited by these Examples.

### Example 1

GaN-HEMTs having the configuration shown in FIG. 1 were fabricated as follows.

A semi-insulating SiC substrate 101 prepared as a base substrate 101 was washed with a mixture of sulfuric acid and hydrogen peroxide, and then heated to 600° C. in a MOCVD furnace. Thereafter, 40 sccm of TMA was supplied from a chamber under the following conditions: the temperature of the constant temperature tank; 30° C., and the flow rates of carrier gases of hydrogen and ammonia; 60SLM and 40SLM, respectively. Then, AlN was grown as a buffer layer 102 to a thickness of 500 Å.

Subsequently, the temperature of the base substrate 101 was changed to 1,150° C., and the flow rate of TMA was adjusted to 0 sccm. Then, 40 sccm of TMG was supplied from the constant temperature tank of 30° C., and a GaN layer was laminated on a buffer layer 102 as a semiconductor crystal layer 103 to a thickness of 2 μm.

Subsequently, the flow rate of TMG was changed to 100 sccm, and 3 sccm of TMA was supplied from the constant temperature tank of 30° C. Then, ud-AlGaN whose Al content was 0.2 was grown as a semiconductor crystal layer A104 to a thickness of 400 Å. Thereafter, the temperature of the base substrate 101 was fallen to about room temperature, and the substrate was then removed from a reactor.

Resist openings were then formed so as to correspond to the shapes of a source electrode and a drain electrode by photolithography, and Ti/Al/Ni/Au metal films were laminated respectively to thicknesses of 200 Å/1,500 Å/250 Å/500 Å by an EB evaporation. Thereafter, the metal films other than openings were removed by a lift-off method to form a source electrode 105 and a drain electrode 106. In order to improve an ohmic characteristic continuously, RTA treatment was conducted at 800° C. for 30 seconds in a nitrogen atmosphere.

The substrate was removed, and a resist pattern was then formed by photolithography, which was used as a mask. Subsequently, N⁺ ion implantation was performed to form a separating layer 107 to a depth of 3,000 Å. The dose amount of N⁺ ions was 2×10¹⁴ ion/cm². After ion implantation, the resist was removed.

Then, a resist opening was provided at the region forming a gate insulation film by photolithography, followed by washing the opening with a diluted HCl aqueous solution. The resulting opening was moved to a spattering equipment, and Hf_{0.6}Al_{0.4}O₂ was laminated by RF spattering. Three levels of samples were prepared, which samples differ in thickness, i.e. 8 nm (Sample 1), 16 nm (Sample 2) and 24 nm (Sample 3). As a gas for spattering the base substrate 101, Ar was used. The spattering power was 0.48 kW. The reactor voltage during spattering was 0.45 Pa. Sintered compact of Hf_{0.6}Al_{0.4}O₂ was used as a spattering target. Subsequently, a gate insulation film 108 was formed by lift-off.

Then, after forming an opening so as to correspond to the shape of the gate electrode by photolithography in a similar manner, Ni/Au metal films were formed to thicknesses of 200 Å/1000 Å by electron beam evaporation, followed by lift-off in the same manner as in the case of the source electrode. As a result, a gate electrode 109 was formed.

The base substrate 101 thus treated was moved to an annealing furnace, and subjected to annealing at 500° C. for 30 minutes in a nitrogen atmosphere.

As described above, three GaN-HEMTs which have the same gate length and width of 2 μm and 30 μm but vary in the thickness of gate insulation film, i.e. GaN-HEMT1 (gate insulation film: 8 nm), GaN-HEMT2 (gate insulation film: 16 nm) and GaN-HEMT3 (gate insulation film: 24 nm) were produced.

A shot key diode was produced in the same process as in the case of the GaN-HEMT1 to perform CV measurement of the GaN-HEMT1. As a result, it has been found that a relative dielectric constant of a gate insulation film was 16.

The gate current density versus gate voltage characteristics of each GaN-HEMTs prepared as described above, i.e. GaN-HEMT1, GaN-HEMT2 and GaN-HEMT3, were measured under the condition of two terminals at the drain electrode ground. The measurement results are shown in FIG. 3.

Further, the transition characteristics of drain current density of each GaN-HEMTs, i.e. GaN-HEMT 1, GaN-HEMT2 and GaN-HEMT3 were measured under the condition of three terminals at source electron ground. During the measurement, 20 volt of bias was applied to the drain electrode. The measurement results are shown in FIG. 4.

The hysteresis characteristics of drain current density versus drain voltage curve of the GaN-HEMT1 were measured. During the measurement, −2 volt of voltage was applied to the gate electrode. The measurement results are shown in FIG. 6.

### Comparative Example 1

A cross-sectional schematic view of a semiconductor integrated circuit including GaN-HEMTs prepared as a Comparative Example is shown in FIG. 2. The structural difference between an embodiment of the present invention shown in FIG. 1 and the Comparative Example shown in FIG. 2 is that no gate insulation film is provided on each field effect transistor in the Comparative Example, but they are the same in other structures. In FIG. 2, a base substrate is expressed at the reference numeral 201, a buffer layer at 202, a semiconductor crystal layer B at 203, a semiconductor crystal layer A at 204, a source electrode at 205, a drain electrode at 206, a separating layer at 207 and a gate electrode at 208.

In the same manner as in Example 1, a SiC substrate was used as a substrate 201 on which an AlN layer was formed as a buffer layer 202 to a thickness of 500 Å; then a GaN layer was formed as a semiconductor crystal layer B203 to a thickness of 2 μm; and finally a ud-AlGaN layer whose Al content was 0.20 was formed as a semiconductor crystal layer A204 to a thickness of 400 Å. Thereafter, the temperature of the base substrate 201 thus treated was fallen to about room temperature, and the substrate was then removed from a reactor as an epitaxial substrate.

A source electrode 205, a drain electrode 206 and a separating layer 207 were formed on the epitaxial substrate removed from the reactor in the same manner as in Example 1. Thereafter, an opening was formed so as to correspond to the shape of a gate electrode by lithography without laminating a gate insulation film, followed by washing with a diluted HCl aqueous solution. A gate electrode 208 was then formed in the same manner as described in Example 1. A GaN-HEMT4 having a gate length of 2 μm and a gate width of 30 μm was thus produced.

The gate current density versus gate voltage characteristics of this GaN-HEMT4 were measured under the condition of two terminals at a drain electrode ground. The measurement results are shown in FIG. 3.

Further, the transition characteristics of drain current density of the GaN-HEMT4 were measured under the condition of three terminals at a source electrode ground. During the measurement, 20 volt of bias was applied to the drain electrode. The measurement results are shown in FIG. 4.

### Comparative Example 2

In the same manner as in Example 1, the following layers were grown on a SiC substrate as a base substrate 201 sequentially; an AlN buffer layer 202 to a thickness of 500 Å; then a GaN semiconductor crystal layer B203 to a thickness of 2 μm; and finally an ud-AlGaN semiconductor crystal layer A204 to a thickness of 400 Å in which Al content of ud-AlGaN was 0.20.

In the same manner as in Example 1, a separating layer 207, a source electrode 205, a drain electrode 206, a gate insulation film (thickness: 8 nm) and a gate electrode 208 were then formed on the base substrate 201 thus treated, followed by formation of necessary electrodes. Annealing treatment was not performed. A GaN-HEMT5 with a gate length of 2 μm and a gate width of 30 μm was thus produced.

The hysteresis characteristics of drain current density versus drain voltage curve of the GaN-HEMT5 were measured. Then, −2 volt of voltage was applied to the gate electrode. The measurement results are shown in FIG. 5.

Referring to FIG. 3, a gate current was reduced dramatically in the GaN-HEMT1, the GaN-HEMT2 and the GaN-HEMT3 produced in Example 1, compared to the GaN-HEMT4 in Comparative Example 1. In particular, it is noted that the effect of suppressing a gate current at the time of applying a forward gate bias was improved significantly. As is apparent from FIG. 3, it was possible to increase amplitude of applied forward voltage up to +8 V for the GaN-HEMT1 and the GaN-HEMT3 as well as up to +9 V for the GaN-HEMT2.

Meanwhile, in the case of the GaN-HEMT4, more than 0 V of gate voltage could not be applied due to a large leak current which was generated when the gate voltage exceeded more than 0 V.

Referring to FIG. 4, the maximum drain current densities of each GaN-HEMT1, GaN-HEMT2 and GaN-HEMT3 in Example 1 were improved to about 95%, 105% and 115% respectively, compared to that of the GaN-HEMT4 in Comparative Example 1.

In FIG. 6, the difference, in the case of changing the sweep direction of the drain current density versus drain voltage curve of the GaN-HEMT1 in Example 1, was much smaller than that of the GaN-HEMT4 shown in FIG. 5. Accordingly, a hysteresis was confirmed to be reduced dramatically by annealing treatment.

### BRIEF DESCRIPTION OF THE DRAWINGS

FIG. 1 is a cross-sectional schematic view showing an embodiment of the present invention;

FIG. 2 is a cross-sectional schematic view showing a device in Comparative Examples;

FIG. 3 is a graph showing the gate current density versus gate voltage characteristics in Example 1 and Comparative Example 1;

FIG. 4 is a graph showing the transition characteristics of drain current density in Example 1 and Comparative Example 1;

FIG. 5 is a graph showing the hysteresis characteristics of drain current versus drain voltage curves in Comparative Example 2; and

FIG. 6 is a graph showing the hysteresis characteristics of drain current versus drain voltage curves in Example 1.

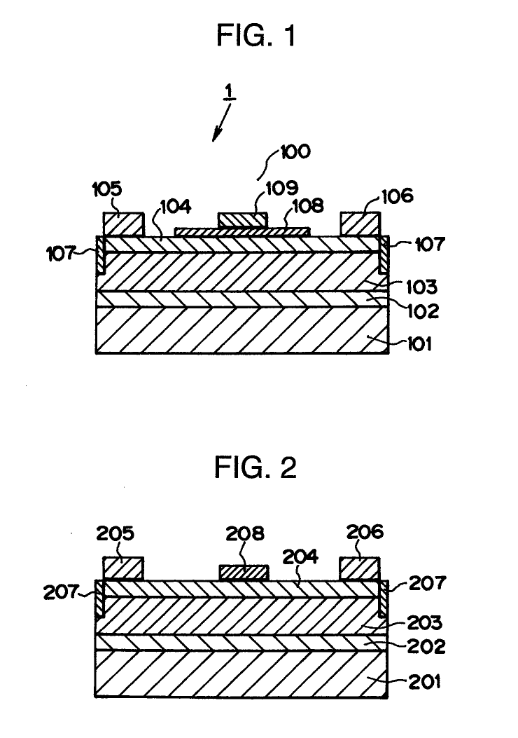

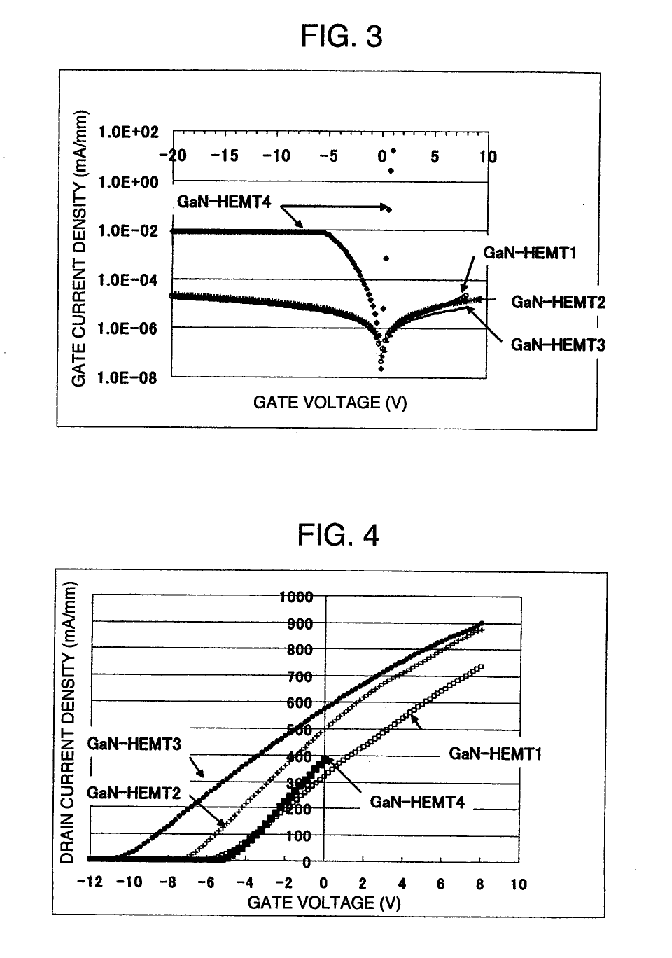

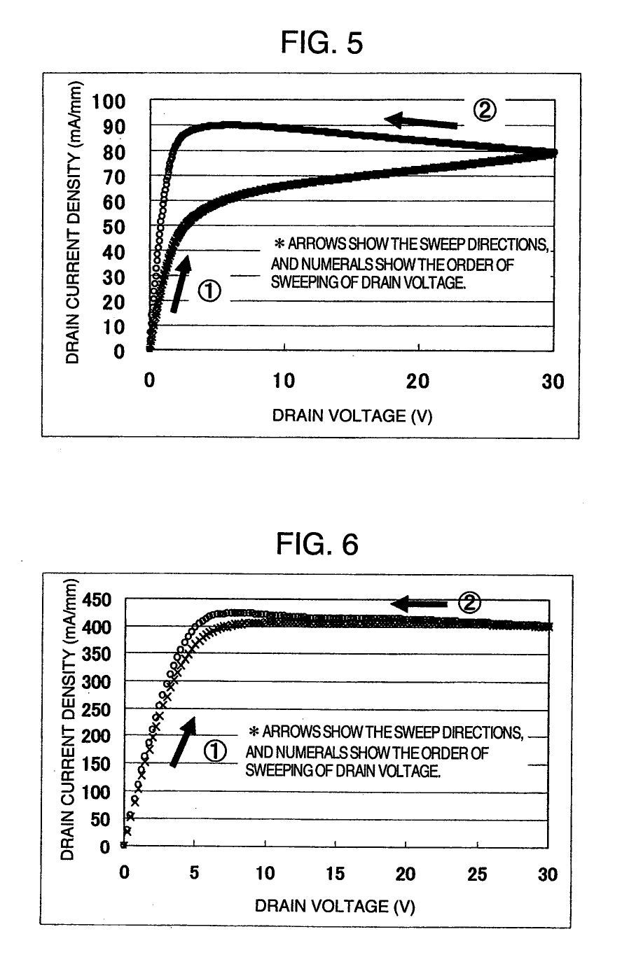

### DESCRIPTION OF REFERENCE NUMERALS

101, 201 Base substrate
102, 202 Buffer layer
103, 203 Semiconductor crystal layer B
104, 204 Semiconductor crystal layer A
105, 205 Source electrode
106, 206 Drain electrode
107, 207 Separating layer
108 Gate insulation film
109, 208 Gate electrode

1. A gallium nitride semiconductor field effect transistor having a gate insulation film and a hetero junction composed of a semiconductor crystal layer A and a semiconductor crystal layer B, wherein a part or all of a material constituting the gate insulation film is a dielectric material having a relative dielectric constant of 9 or more to 22 or less, and wherein the semiconductor crystal layer A is in contact with the gate insulation film and the semiconductor crystal layer B in the vicinity of the semiconductor crystal layer A has a larger electron affinity than the semiconductor crystal layer A.

2. The semiconductor field effect transistor according to claim 1, wherein the semiconductor crystal layer A is AlₓIN_{y}Ga_{(1-x-y)}N crystal (0≦x, y≦1, x+y≦1).

3. The semiconductor field effect transistor according to claim 1, wherein a part or all of the material constituting the gate insulation film comprises a hafnium oxide.

4. The semiconductor field effect transistor according to claim 1, wherein a part or all of the material constituting the gate insulation film comprises HfₓAl₁₋ₓO_{y} (0<x<1, 1≦y≦2).

5. A semiconductor integrated circuit comprising the field effect transistor according to claims 1.

6. A method for fabricating the semiconductor field effect transistor according to claims 1, comprising the steps of:
forming an insulation layer; and
then performing heat treatment at a temperature of 300° C. or higher.

7. The method for fabricating the semiconductor field effect transistor according to claim 6, comprising the steps of:
forming a gate electrode; and then
performing heat treatment at a temperature of 300° C. or higher.

8. A method for fabricating the semiconductor integrated circuit according to claim 5, comprising the steps of:
forming an insulation layer; and
then performing heat treatment at a temperature of 300° C. or higher.

9. The method for fabricating the semiconductor integrated circuit according to claim 8, comprising the steps of:
forming a gate electrode; and then
performing heat treatment at a temperature of 300° C. or higher.

10. The semiconductor field effect transistor according to claim 2, wherein a part or all of the material constituting the gate insulation film comprises a hafnium oxide.
